(19) United States
(12) Patent Application Publication
(10) Pub. No.: US 2021/0037671 A1
(43) Pub. Date: Feb. 4, 2021

(54) PUSH-PULL HANDLE MODULE

(71) Applicant: PEGATRON CORPORATION, Taipei City (TW)

(72) Inventors: Long-Sing Ye, Taipei City (TW); Yao-Hsien Huang, Taipei City (TW)

(73) Assignee: PEGATRON CORPORATION, Taipei City (TW)

(21) Appl. No.: 16/899,498

(22) Filed: Jun. 11, 2020

(30) Foreign Application Priority Data
Aug. 2, 2019 (TW) 108127563

(51) Int. Cl. H05K 7/14

(52) U.S. Cl. CPC H05K 7/1489; H05K 7/1401

(57) ABSTRACT

A push-pull handle module is adapted to lock at least one electronic module in a rack. The push-pull handle module includes a bracket and a handle. The bracket is fixed to the at least one electronic module and includes a slot. The handle is pivotally connected to the bracket and includes a protrusion and a locking portion. The protrusion is slidably disposed into the slot of the bracket. When the handle is in a first position, the locking portion locks rack the at least one electronic module in the rack. When the handle rotates from the first position to a second position relative to the bracket, the locking portion does not lock the at least one electronic module.

### CROSS-REFERENCE TO RELATED APPLICATION

This application claims the priority benefit of Taiwan application serial no. 108127563, filed on Aug. 2, 2019. The entirety of the above-mentioned patent application is hereby incorporated by reference herein and made a part of this specification.

### BACKGROUND

### Technical Field

The disclosure relates to a mechanical module, and in particular, to a push-pull handle module.

### Description of Related Art

Conventional push-pull handles only have a hooking function. Therefore, when a server is placed in a rack, a handle needs to be additionally disposed to pull the server out of the rack. Moreover, the conventional push-pull handles do not have a limiting mechanism to limit angles while opening and closing, and a user can only pull the server out of the rack after confirming, by the observation or the feeling of a movement, that the hooking portion is detached. In addition, a user is aware of whether the server is operating only through a sign stuck or hung on the server. Therefore, with the conventional push-pull handles, it is difficult to identify the operation state intuitively, which may cause a misjudgement on the operation state and the server gets pulled out by mistake.

### SUMMARY

The invention provides a push-pull handle module to provide a convenient and intuitive operation to a user.

The push-pull handle module of the invention is adapted to lock at least one electronic module in a rack. The push-pull handle module includes a bracket and a handle. The bracket is fixed to the at least one electronic module and includes a slot. The handle is pivotally connected to the bracket and includes a protrusion and a locking portion. The protrusion is slidably disposed into the slot of the bracket. When the handle is in a first position, the locking portion locks the at least one electronic module in the rack. When the handle rotates from the first position to a second position relative to the bracket and thereby the protrusion moves along the slot, the locking portion does not lock the at least one electronic module, and the handle is adapted to pull the at least one electronic module out of the rack.

In an embodiment of the invention, the push-pull handle module further includes a connecting assembly, pivotally connected to the bracket and the handle, where the handle rotates around the connecting assembly, relative to the bracket.

In an embodiment of the invention, the bracket is provided with a first limiting hole, the handle is provided with a second limiting hole, and the connecting assembly is provided with a first limiting portion and a second limiting portion on opposite sides. The first limiting portion penetrates the first limiting hole, and the second limiting portion penetrates the second limiting hole.

In an embodiment of the invention, the bracket is provided with a first limiting hole, the handle is provided with a second limiting hole, and the connecting assembly includes a screw and a nut. The screw passes through the first limiting hole and the second limiting hole and is fastened to the nut.

In an embodiment of the invention, the handle further includes a first color block and a second color block at two sides of the protrusion. When the handle is in the first position, the first color block is exposed from the slot. When the handle is in the second position, the second color block is exposed from the slot.

In an embodiment of the invention, the handle further includes a spring plate portion. When the handle is in the first position, the spring plate portion interferes with the bracket to fix the handle to the bracket.

In an embodiment of the invention, the handle further includes a grip portion, and the handle is capable of rotating relative to the bracket when the grip portion is lifted.

In an embodiment of the invention, the push-pull handle module further includes a protective shell, including a first covering portion and a second covering portion which are detachably assembled, where the first covering portion and the second covering portion enclose the grip portion.

In an embodiment of the invention, the handle further includes a pressing portion. When the handle is in the second position, the pressing portion abuts against the at least one electronic module.

In an embodiment of the invention, the push-pull handle module further includes at least one fastener, and the bracket further includes at least one fixing portion, where the fastener passes through the fixing portion to fix the bracket to the at least one electronic module.

In an embodiment of the invention, the electronic module includes at least one application of a related data center hardware system such as a switch or a server.

Based on the above, in the push-pull handle module of the invention, the protrusion of the handle is slidably disposed in the slot of the bracket, so that the handle can pivot relative to the bracket, and move along the slot to rotate between the first position and the second position relative to the bracket. When the handle is in the first position, the locking portion can lock the rack to fix the electronic module in the rack. When the handle is in the second position, the locking portion does not lock the rack, so that the user can pull the electronic module in the rack out of the rack through the handle. In this way, the push-pull handle module of the invention can provide convenience and intuition in operation to the user.

To make the features and advantages of the invention clear and easy to understand, the following gives a detailed description of embodiments with reference to accompanying drawings.

### BRIEF DESCRIPTION OF THE DRAWINGS

FIG. 1A is a three-dimensional exploded view of a push-pull handle module according to an embodiment of the invention.

FIG. 1B is a three-dimensional exploded view of the push-pull handle module in FIG. 1A from another angle of view and a case of an electronic module.

FIG. 2A to FIG. 2C are three-dimensional views of the push-pull handle module in FIG. 1A locking an electronic module in a rack, with a handle rotating between a first position and a second position.

FIG. 3 is a partial three-dimensional cross-sectional view of the push-pull handle module in FIG. 1A locking an electronic module in a rack.

FIG. 4 is a partial three-dimensional cross-sectional view of the push-pull handle module in FIG. 1A abutting against the electronic module.

FIG. 5 is a three-dimensional exploded view of a push-pull handle module according to another embodiment of the invention.

### DESCRIPTION OF THE EMBODIMENTS

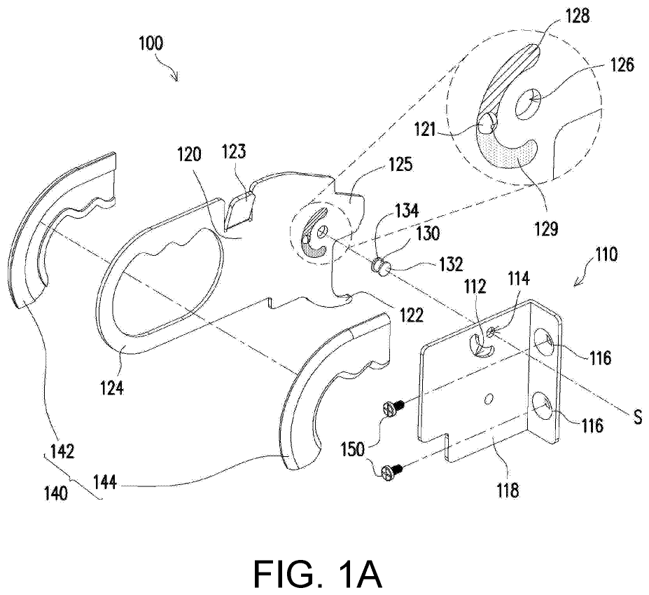

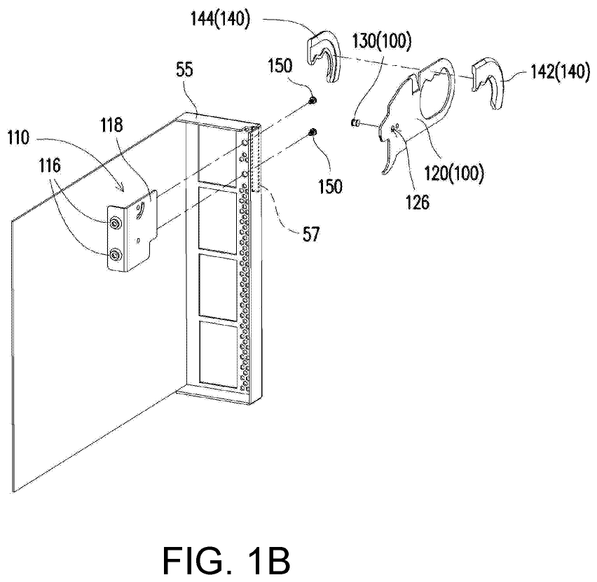

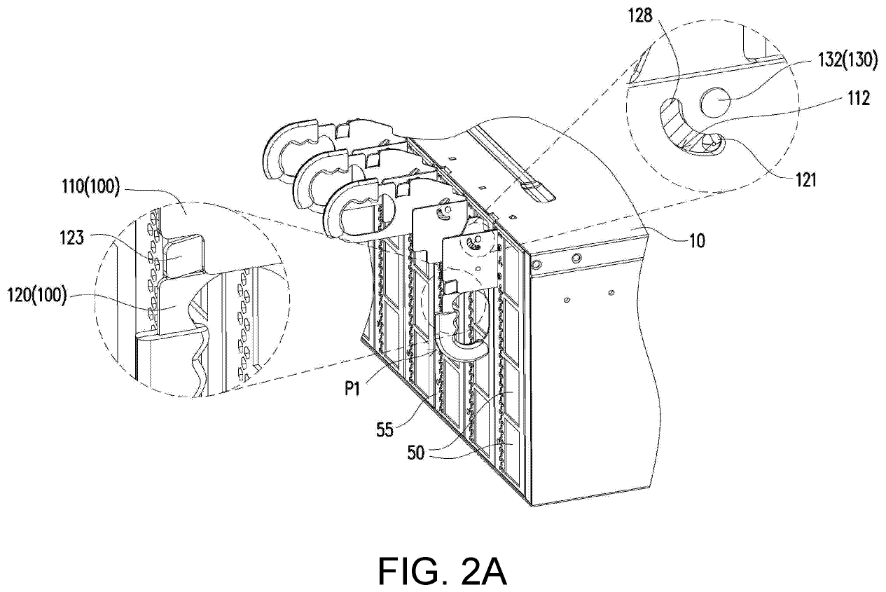

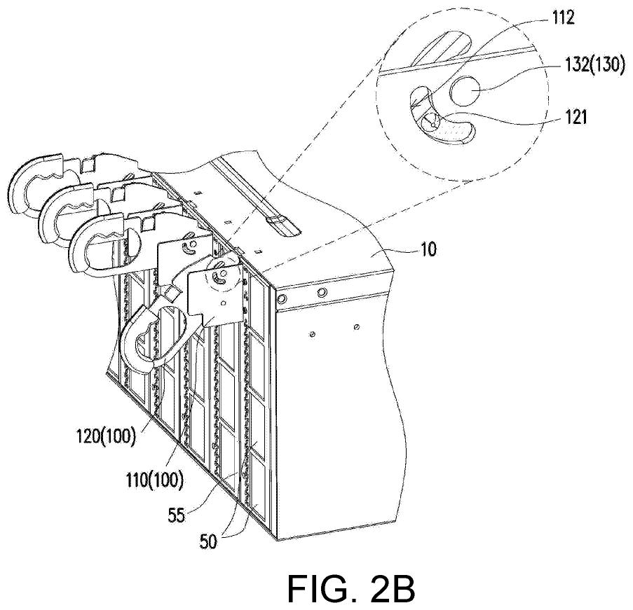

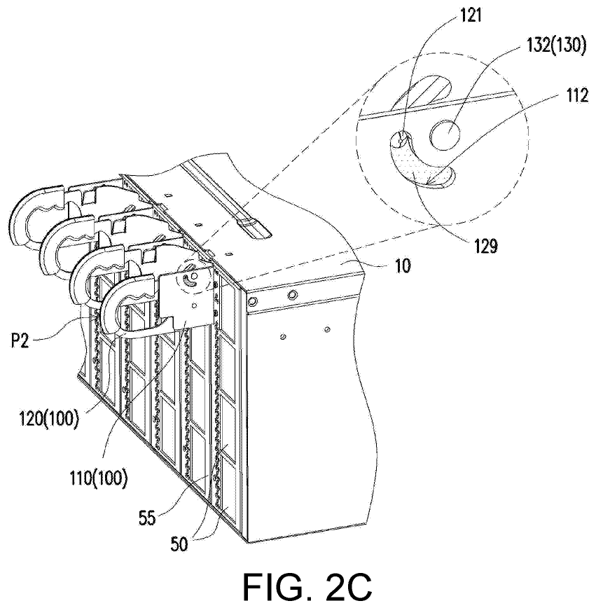

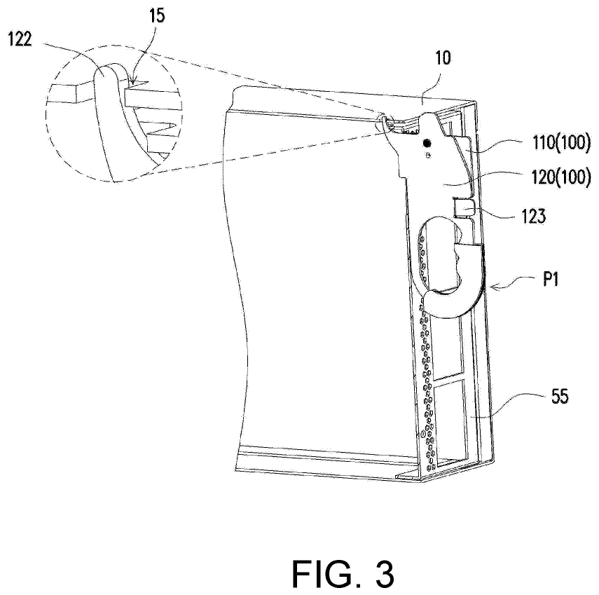

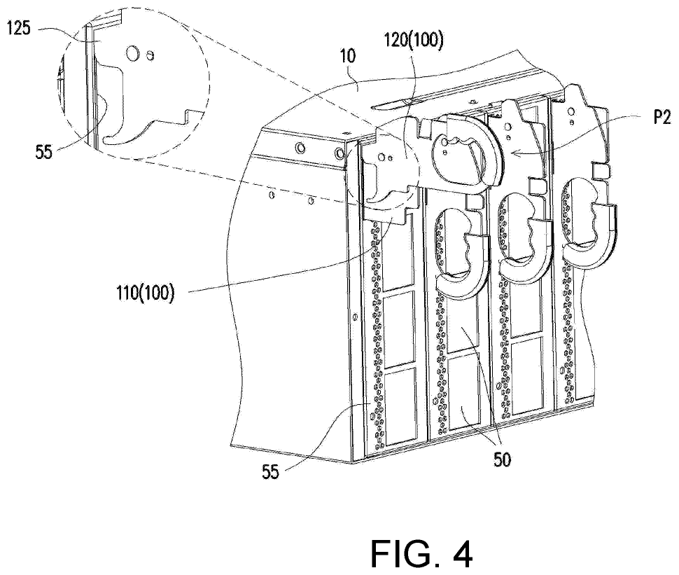

FIG. 1A is a three-dimensional exploded view of a push-pull handle module according to an embodiment of the invention. FIG. 1B is a three-dimensional exploded view of the push-pull handle module in FIG. 1A from another angle of view and a case of an electronic module. FIG. 2A to FIG. 2C are three-dimensional views of the push-pull handle module in FIG. 1A locking an electronic module in a rack, with a handle rotating between a first position and a second position. FIG. 3 is a partial three-dimensional cross-sectional view of the push-pull handle module in FIG. 1A locking an electronic module in a rack. FIG. 4 is a partial three-dimensional cross-sectional view of the push-pull handle module in FIG. 1A abutting against an electronic module. For ease of description, FIG. 3 omits to show the electronic module.

First, referring to FIG. 1A, FIG. 1B, FIG. 2A, and FIG. 3, in the present embodiment, a push-pull handle module 100 is adapted to lock at least one electronic module in a rack 10. At least one electronic module (a plurality of electronic modules 50 is schematically shown) is disposed in the rack 10. Herein, the electronic module 50 is related to, for example, a hardware system of a data center such as a switch or a server, but the invention is not limited thereto. In other embodiments, the push-pull handle module 100 may be mounted on any device that needs to be pushed in and pulled out, which still falls within the protection scope of the invention.

Specifically, the push-pull handle module 100 of the present embodiment includes a bracket 110 and a handle 120. The bracket 110 is fixed on a case 55 of the electronic module 50 and includes a slot 112. The handle 120 is pivotally connected to the bracket 110, and the handle 120 includes a protrusion 121 and a locking portion 122. The protrusion 121 of the handle 120 is slidably disposed into the slot 112 of the bracket 110 to limit the protrusion 121 in the slot 112 so that the handle 120 is pivoted between a first position P1 (referring to FIG. 2A and FIG. 3) and a second position P2 (referring to FIG. 2C and FIG. 4) relative to the bracket 110. Certainly, in other embodiments, the handle 120 may also be limited without the protrusion 121 or by other suitable structure designs, for example, interference according to practical requirements as long as the handle 120 is able to rotate between the first position P1 and the second position P2 relative to the bracket 110, which still falls within the protection scope of the invention.

Moreover, in the present embodiment, the push-pull handle module 100 further includes a connecting assembly 130. The connecting assembly 130 is pivotally connected to the bracket 110 and the handle 120, and the handle 120 rotates around the connecting assembly, relative to the bracket. Further, the bracket 110 is provided with a first limiting hole 114, and the handle 120 is provided with a second limiting hole 126. The connecting assembly 130 is provided with a first limiting portion 132 and a second limiting portion 134 on the opposite sides. Preferably, the first limiting portion 132 of the connecting assembly 130 penetrates the first limiting hole 114 of the bracket 110, and the second limiting portion 134 of the connecting assembly 130 penetrates the second limiting hole 126 of the handle 120. Herein, the connecting assembly 130 is, for example, a rivet, but is not limited thereto. The first limiting portion 132 and the second limiting portion 134 of the connecting assembly 130 pass through the first limiting hole 114 of the bracket 110 and the second limiting hole 126 of the handle 120. The bracket 110 and the handle 120 are connected in a riveting manner to limit displacements of the handle 120 and the bracket 110 in an axis S direction so that the handle 120 is pivotally connected to the bracket 110. Based on such design, the handle 120 may use the connecting assembly 130 as a center and only rotate around the bracket 110, rather than move back and forth relative to the bracket 110.

Then, referring to FIG. 1A and FIG. 1B, in the present embodiment, the push-pull handle module 100 further includes at least one fastener (two fasteners 150 are schematically shown), and the bracket 110 further includes at least one fixing portion (two fixing portions 116 are schematically shown). The fastener 150 passes through the fixing portion 116 to fix the bracket 110 on the case 55 of the electronic module 50. More specifically, the case 55 of the electronic module 50 is provided with a slot 57 corresponding to the bracket 110. A body portion 118 of the bracket 110 passes through the slot 57, and the fastener 150 passes through the case 55 and the fixing portion 116 sequentially to fix the bracket 110 on the case 55 of the electronic module 50. Herein, the fastener 150 is, for example, a screw or a bolt, and the fixing portion 116 is, for example, a fastening hole, but is not limited thereto.

Referring to FIG. 1A and FIG. 2A, the handle 120 of the present embodiment further includes a spring plate portion 123 used for interfering with the bracket 110 when the handle 120 is in the first position P1 to fix the handle 120 to the bracket 110. Moreover, the handle 120 may further include a grip portion 124. A user may rotate the handle 120 relative to the bracket 110 by lifting the grip portion 124. Optionally, the push-pull handle module 100 of the present embodiment further includes a protective shell 140, which includes a first covering portion 142 and a second covering portion 144 that are assembled detachably. The first covering portion 142 and the second covering portion 144 enclose the grip portion 124 so it is convenient for the user to lift the grip portion 124. In addition, referring to FIG. 1A and FIG. 4, the handle 120 of the present embodiment may further include a pressing portion 125 used for abutting against the case 55 of the electronic module 50. Particularly, the handle 120 of the present embodiment further includes a first color block 128 and a second color block 129 at two sides of the protrusion 121. Through the rotation of the handle 120 relative to the bracket 110, the colors of the color blocks may be selectively displayed, so that it is more intuitive for the user to identify whether the electronic module 50 is in the operation state. Therefore, the push-pull handle module 100 of the present embodiment can show the operation state of the electronic module 50 without additional colored tape label.

In operation, referring to FIG. 2A and FIG. 3, when the handle 120 is in the first position P1, the locking portion 122 of the handle 120 hooks a locking hole 15 (as shown in FIG. 3) of the rack 10 to lock the electronic module 50 in the rack 10. In this case, the spring plate portion 123 of the handle 120 interferes with the bracket 110 to fix the handle 120 at the lower part of the bracket 110. The first color block 128 is exposed from the slot 112, so that the user can clearly learn that the electronic module 50 is in the rack 10 and is in the operation state. That is, when the handle 120 is in the first position P1, the electronic module 50 is in the rack 10 and running.

Next, referring to FIG. 2A, FIG. 2B, and FIG. 2C, when the user intends to rotate the handle 120 from the first position P1 to the second position P2 (referring to FIG. 2C), the handle 120 cannot be rotated until the spring plate portion 123 of the handle 120 is pressed to release the interference of the spring plate portion 123 with the bracket 110. Herein, the spring plate portion 123 of the handle 120 is a fool-proof design to avoid a situation in which the handle 120 is loosened or the user mistakenly pulls the handle 120 by unintended contact during the operation of the electronic module 50.

Then, referring to FIG. 2B, FIG. 2C and FIG. 4, when the protrusion 121 moves along the slot 112 to rotate the handle 120 from the first position P1 (referring to FIG. 2A) to the second position P2 relative to the bracket 110, the locking portion 122 does not hook the rack 10 and releases the fixed relationship between the electronic module 50 and the rack 10. In this case, the handle 120 is in the second position P2, the second color block 129 is exposed from the slot 112 of the bracket 110, and the pressing portion 125 of the handle 120 abuts against the case 55 of the electronic module 50. The user can pull the electronic module 50 out of the rack 10 by pushing the pressing portion 125 of the handle 120.

Briefly, when the user uses the push-pull handle module 100 of the present embodiment, it is more intuitive for the user to determine, through the first color block 128 and the second color block 129 of the handle 120, whether the electronic module 50 is currently in the operation state, and thereby intuitive and convenient operation experience is provided to the user. On the other hand, the design of the first color block 128 and the second color block 129 of the handle 120 can prevent the user from pulling the electronic module 50 by mistake. Moreover, the handle 120 of the push-pull handle module 100 of the present embodiment has the design of both the locking portion 122 and the grip portion 124, which not only is more convenient in an operation of pushing in or pulling out the electronic module 50, but also reduces material costs without an additional carrying handle. In addition, in the push-pull handle module 100 of the present embodiment, through a rotation mechanism of the handle 120 and the bracket 110, the user just needs to push the handle 120 all the way to the end and pulls out the electronic module 50, thereby making the operation intuitive and convenient.

It should be noted that, in the present embodiment, the first color block 128 is used for representing that the electronic module 50 operates in the operation state, and the second color block 129 is used for representing that the electronic module 50 operates in a non-operation state. The first color block 128 is, for example, a red color block, and the second color block 129 is, for example, a blue color block. Certainly, in other embodiments, the color of the red color block may be replaced with another striking color (for example, yellow), which still falls within the protection scope of the invention.

Herein it should be noted that, the following embodiment still uses the element numbers and some content of the foregoing embodiment, where same numbers are used for representing same or similar elements, and description of the same technical content is omitted. For the description of the omitted part, reference may be made to the foregoing embodiment, and the following embodiment does not repeat the description.

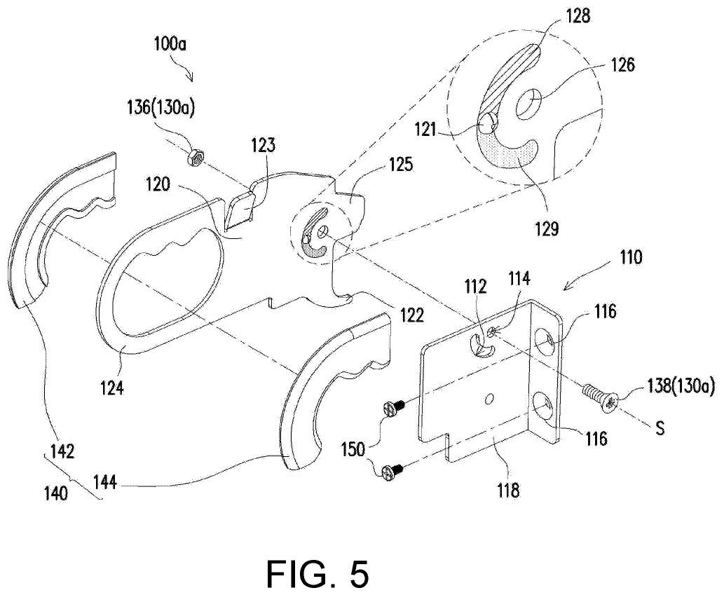

FIG. 5 is a three-dimensional exploded view of a push-pull handle module according to another embodiment of the invention. Referring to FIG. 1A and FIG. 5, the push-pull handle module 100a of the present embodiment is similar to the push-pull handle module 100 in FIG. 1A, and the difference lies in: a structural form of the connecting assembly 130a of this embodiment is different from that of the connecting assembly 130 in FIG. 1A. Specifically, the connecting assembly 130a of this embodiment includes a screw 138 and a nut 136, where the screw 138 passes through the first limiting hole 114 of the bracket 110 and the second limiting hole 126 of the handle 120 to be fastened to the nut 136. Therefore, displacements of the handle 120 and the bracket 110 in an axis S direction are limited, and the handle 120 is pivotally connected to the bracket 110. Certainly, in other embodiments (not shown), in addition to the design in the forms of the nut 136 and the screw 138, the connecting assembly 130a may also have other designs in suitable forms, but the invention is not limited thereto.

Based on the above, in the push-pull handle module of the invention, the protrusion of the handle is slidably disposed into the slot of the bracket, so that the handle can pivot relative to the bracket. When the protrusion of the handle moves along the slot, the handle rotates between the first position and the second position relative to the bracket. When the handle is in the first position, the locking portion can lock the electronic module in the rack. When the handle is in the second position, the locking portion does not lock the electronic module, so that the user can pull the electronic module out of the rack through the handle. In this way, the push-pull handle module of the invention can provide convenience and intuition in operation to the user.

Although the invention is described with reference to the above embodiments, the embodiments are not intended to limit the invention. A person of ordinary skill in the art may make variations and modifications without departing from the spirit and scope of the invention. Therefore, the protection scope of the invention should be subject to the appended claims.

What is claimed is:

1. A push-pull handle module, adapted to lock at least one electronic module in a rack, and the push-pull handle module comprises:
a bracket, fixed to the at least one electronic module and comprising a slot; and
a handle, pivotally connected to the bracket and comprising a protrusion and a locking portion, wherein the protrusion is slidably disposed into the slot of the bracket, wherein when the handle is in a first position, the locking portion locks the at least one electronic module in the rack, and when the handle rotates from the first position to a second position relative to the bracket and thereby the protrusion moves along the slot, the locking portion does not lock the at least one electronic module to pull the at least one electronic module out of the rack.

2. The push-pull handle module according to claim 1, further comprising:
a connecting assembly, pivotally connected to the bracket and the handle, wherein the handle rotates around the connecting assembly, relative to the bracket.

3. The push-pull handle module according to claim 2, wherein the bracket is provided with a first limiting hole, the handle is provided with a second limiting hole, the connecting assembly is provided with a first limiting portion and a second limiting portion on opposite sides, the first limiting portion penetrates the first limiting hole, and the second limiting portion penetrates the second limiting hole.

4. The push-pull handle module according to claim 2, wherein the bracket is provided with a first limiting hole, the handle is provided with a second limiting hole, the connecting assembly comprises a screw and a nut, and the screw passes through the first limiting hole and the second limiting hole and is fastened by the nut.

5. The push-pull handle module according to claim 1, wherein the handle further comprises a first color block and a second color block at two sides of the protrusion, wherein when the handle is in the first position, the first color block is exposed from the slot, and when the handle is in the second position, the second color block is exposed from the slot.

6. The push-pull handle module according to claim 1, wherein the handle further comprises a spring plate portion, and when the handle is in the first position, the spring plate portion interferes with the bracket to fix the handle to the bracket.

7. The push-pull handle module according to claim 1, wherein the handle further comprises a grip portion and the handle is capable of rotating relative to the bracket when the grip portion is lifted.

8. The push-pull handle module according to claim 7, further comprising:
a protective shell, comprising a first covering portion and a second covering portion which are detachably assembled, wherein the first covering portion and the second covering portion enclose the grip portion.

9. The push-pull handle module according to claim 1, wherein the handle further comprises a pressing portion, and when the handle is in the second position, the pressing portion abuts against the at least one electronic module.

10. The push-pull handle module according to claim 1, further comprising:
at least one fastener, wherein the bracket further comprises at least one fixing portion, and the fastener passes through the fixing portion to fix the bracket to the at least one electronic module.

11. The push-pull handle module according to claim 1, wherein the electronic module comprises at least one switch or at least one server.
